(19) United States
(12) Patent Application Publication
(10) Pub. No.: US 2024/0162008 A1
(43) Pub. Date: May 16, 2024

(54) METHODS AND APPARATUS FOR PROCESSING A SUBSTRATE

(71) Applicant: Applied Materials, Inc., Santa Clara, CA (US)

(72) Inventors: Yue GUO, Redwood City, CA (US); Kartik RAMASWAMY, San Jose, CA (US); Yang YANG, Cupertino, CA (US); Nicolas John BRIGHT, Mountain Lakes, NJ (US); A N M Wasekul AZAD, Cupertino, CA (US)

(21) Appl. No.: 17/988,083

(22) Filed: Nov. 16, 2022

(51) Int. Cl. H01J 37/32; H03H 11/28

(52) U.S. Cl. CPC H01J 37/32183; H03H 11/28; H01J 2237/327

(57) ABSTRACT

Methods and apparatus for processing a substrate are provided herein. For example, a matching network comprises a first sensor operably connected to an input of the matching network and an RF generator operable at a first frequency and a second sensor operably connected to an output of the matching network and the plasma processing chamber. The first sensor and the second sensor are configured to measure impedance during an RF generator pulse on time. A variable capacitor is connected to the first sensor and the second sensor, and a controller is configured to tune the at least one variable capacitor of the matching network during the RF generator pulse on time based on impedance values measured during at least one of pulse on states or pulse off states of a pulse voltage waveform generator connected to the matching network or an RF signal of another RF generator operable at a second frequency different from the first frequency.

### FIELD

Embodiments of the present disclosure generally relate to methods and apparatus for processing substrates, and for example, to methods and apparatus for processing substrates using impedance lock tuning to pulse voltage generator (PVT).

### BACKGROUND

Methods and apparatus for processing substrates in a vacuum processing chamber using one or more of RF power sources are known (e.g., one or more RF power sources can be configured for single level pulsing, dual level pulsing or multi-level pulsing). For example, in single level pulsing (e.g., pulsing between an on state and an off state), there is only one state to tune to (e.g., the on state). In dual level pulsing, however, the RF power source is switched between a high state and a low state (e.g., not an off state). In multi-level pulsing, the RF power source can be switched between multi states.

An RF matching network is often connected between the RF power source (RF generator) and the vacuum processing chamber and configured to ensure that an output of the RF power source is efficiently coupled to the plasma to maximize an amount of energy coupled to the plasma (e.g., referred to as tuning the RF power delivery). Minimum reflected power to the RF power source is one criteria for successful tuning by the RF matching network. Due to sideband coming back to the RF power source with a PVT pulsed voltage waveform, however, reflected power measured at the RF power source can also be attributed to pulse on time, PVT frequency, match data processing, etc. Thus, using the reflected power at the RF power source to evaluate a match tuning may not work particularly well for the PVT chambers. When the RF matching network tunes to a time averaging impedance, the RF matching network tunes to a combination of PVT on and off impedances (e.g., depending on match signal processing settings).

Thus, the inventors have provided herein improved methods and apparatus for processing substrates using impedance lock tuning to pulse voltage generator (PVT).

### SUMMARY

Methods and apparatus for processing a substrate are provided herein. For example, in some embodiments, a matching network configured for use with a plasma processing chamber comprises a first sensor operably connected to an input of the matching network and an RF generator operable at a first frequency and a second sensor operably connected to an output of the matching network and the plasma processing chamber. The first sensor and the second sensor can be configured to measure impedance during an RF generator pulse on time. At least one variable capacitor can be connected to the first sensor and the second sensor. A controller can be configured to tune the at least one variable capacitor of the matching network during the RF generator pulse on time based on impedance values measured during at least one of pulse on states or pulse off states of a pulse voltage waveform generator connected to the matching network or an RF signal of another RF generator operable at a second frequency different from the first frequency.

In accordance with at least some embodiments, a plasma processing chamber comprises a chamber body and a chamber lid, a RF generator operable at a first frequency connected to the chamber lid and configured to create a plasma from gases disposed in a processing region of the chamber body, and a matching network. The matching network comprises a first sensor operably connected to an input of the matching network and an RF generator operable at a first frequency and a second sensor operably connected to an output of the matching network and the plasma processing chamber. The first sensor and the second sensor can be configured to measure impedance during an RF generator pulse on time. At least one variable capacitor can be connected to the first sensor and the second sensor. A controller can be configured to tune the at least one variable capacitor of the matching network during the RF generator pulse on time based on impedance values measured during at least one of pulse on states or pulse off states of a pulse voltage waveform generator connected to the matching network or an RF signal of another RF generator operable at a second frequency different from the first frequency.

In accordance with at least some embodiments, a method for processing a substrate comprises detecting an RF generator, which is operable at a first frequency, pulse on time at a matching network connected to the RF generator and based on impedance values measured during at least one of pulse on states or pulse off states of a pulse voltage waveform generator connected to the matching network or an RF signal of another RF generator operable at a second frequency different from the first frequency, tuning at least one variable capacitor of the matching network during the RF generator pulse on time.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a cross-sectional view of processing chamber in accordance with at least some embodiments of the present disclosure.

FIG. 2 is a diagram of a system in accordance with at least some embodiments of the present disclosure.

FIG. 3 is diagram of a matching network in accordance with at least some embodiments of the present disclosure.

FIG. 4 is a graph of sampling impedances in accordance with at least some embodiments of the present disclosure.

FIG. 5 is a diagram of a system in accordance with at least some embodiments of the present disclosure.

FIG. 6 is a diagram of internal synchronization for dual level pulsing in accordance with at least some embodiments of the present disclosure.

FIG. 7 is a diagram of internal synchronization for flexible pulsing control, in accordance with at least some embodiments of the present disclosure.

FIG. 8 is a flowchart of a method of processing a substrate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a methods and apparatus for processing a substrate are provided herein. For example, a matching network configured for use with a plasma processing chamber can comprise a first sensor operably connected to an input of the matching network and an RF generator and a second sensor operably connected to an output of the matching network and the plasma processing chamber. The first sensor and the second sensor are configured to measure impedance during an RF generator pulse on time. At least one variable capacitor can be connected to the first sensor and the second sensor. A controller can be configured to tune the at least one variable capacitor of the matching network during the RF generator pulse on time based on impedance values measured during at least one of pulse on states or pulse off states of a pulse voltage waveform generator connected to the matching network. Advantages of the apparatus and methods described herein include, but are not limited to, tuning to an optimized plasma impedance value to achieve minimum total reflected power for all states during multilevel pulsing, faster etch rate when tuning during operation (e.g., PVF), spatial power distribution and uniformity, and flexibility to define tuning targets based on different process and pulsing conditions.

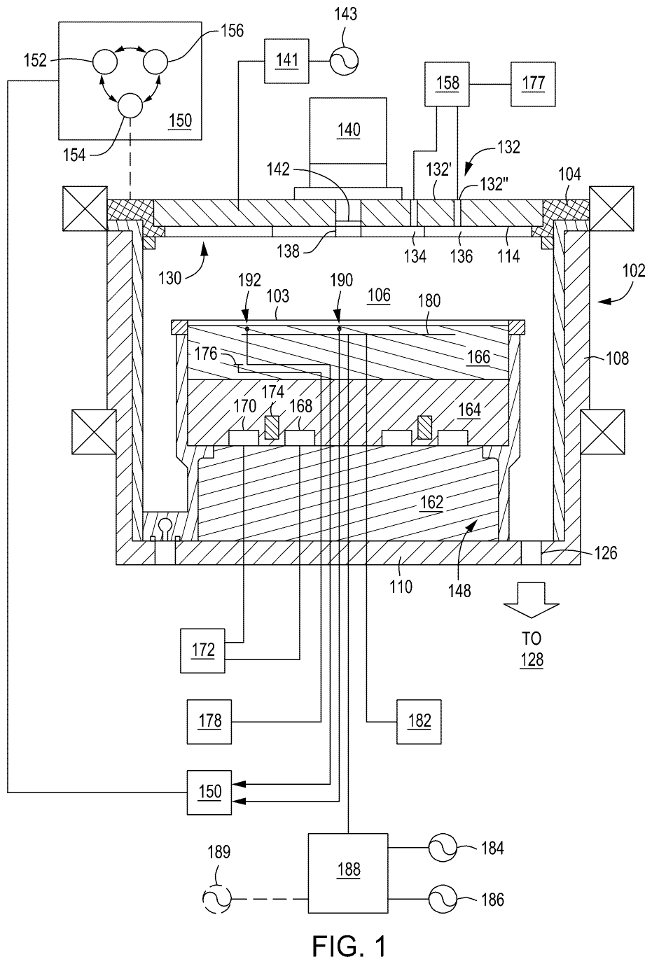

FIG. 1 is a sectional view of one example of a processing chamber 100 suitable for performing an etch process in accordance with the present disclosure. Suitable processing chambers that may be adapted for use with the teachings disclosed herein include, for example, one or more etch processing chambers available from Applied Materials, Inc. of Santa Clara, CA. Other processing chambers may be adapted to benefit from one or more of the methods of the present disclosure.

The processing chamber 100 includes a chamber body 102 and a chamber lid 104 which enclose an interior volume 106. The chamber body 102 is typically fabricated from aluminum, stainless steel or other suitable material. The chamber body 102 generally includes sidewalls 108 and a bottom 110. A substrate support pedestal access port (not shown) is generally defined in a sidewall 108 and a selectively sealed by a slit valve to facilitate entry and egress of a substrate 103 from the processing chamber 100. An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the processing chamber 100. In embodiments, the pump system 128 maintains the pressure inside the interior volume 106 at operating pressures typically between about 1 mTorr to about 500 mTorr, between about 5 mTorr to about 100 mTorr, or between about 5 mTorr to 50 mTorr depending upon process needs.

In embodiments, the chamber lid 104 is sealingly supported on the sidewall 108 of the chamber body 102. The chamber lid 104 may be opened to allow excess to the interior volume 106 of the processing chamber 100. The chamber lid 104 includes a window 142 that facilitates optical process monitoring. In one embodiment, the window 142 is comprised of quartz or other suitable material that is transmissive to a signal utilized by an optical monitoring system 140 mounted outside the processing chamber 100.

The optical monitoring system 140 is positioned to view at least one of the interior volume 106 of the chamber body 102 and/or the substrate 103 positioned on a substrate support pedestal assembly 148 through the window 142. In one embodiment, the optical monitoring system 140 is coupled to the chamber lid 104 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed.

Process gases and/or cleaning gases can be introduced to the interior volume 106 of the chamber body 102 through the showerhead assembly 130 from a gas panel 158, which is coupled to the processing chamber 100. A vacuum pump system such as pump system 128 maintains the pressure inside the chamber body 102 while removing deposition by-products.

In embodiments, the gas panel 158. In the example depicted in FIG. 1, inlet ports 132′, 132″ are provided in the chamber lid 104 to allow gases to be delivered from the gas panel 158 to the interior volume 106 of the processing chamber 100. In embodiments, the gas panel 158 is adapted to provide oxygen and inert gas such as argon, or oxygen and helium process gas or gas mixture through the inlet ports 132′, 132″ and into the interior volume 106 of the processing chamber 100. In one embodiment, the process gas provided from the gas panel 158 includes at least a process gas including an oxidizing agent such as oxygen gas. In embodiments, the process gas including an oxidizing agent may further comprise an inert gas such as argon or helium. In some embodiments, the process gas includes a reducing agent such as hydrogen and may be mixed with an inert gas such as argon, or other gases such as nitrogen or helium. In some embodiments, a chlorine gas may be provided alone, or in combination with at least one of nitrogen, helium an inert gas such as argon. Non-limiting examples of oxygen containing gas includes one or more of O₂, CO₂, N₂O, NO₂, O₃, H₂O, and the like. Non-limiting examples of nitrogen containing gas includes N₂, NH₃, and the like. Non-limiting examples of chlorine containing gas includes HCl, Cl₂, CCl₄, and the like. In embodiments, a showerhead assembly 130 is coupled to an interior surface 114 of the chamber lid 104. The showerhead assembly 130 includes a plurality of apertures that allow the gases flowing through the showerhead assembly 130 from the inlet ports 132′, 132″ into the interior volume 106 of the processing chamber 100 in a predefined distribution across the surface of the substrate 103 being processed in the processing chamber 100.

In some embodiments, the processing chamber 100 may utilize capacitively coupled RF energy for plasma processing, or in some embodiments, processing chamber 100 may use inductively coupled RF energy for plasma processing. In some embodiments, a remote plasma source 177 may be optionally coupled to the gas panel 158 to facilitate dissociating gas mixture from a remote plasma prior to entering the interior volume 106 for processing. In some embodiments, a RF source power 143 is coupled through a matching network 141 to the showerhead assembly 130. The RF source power 143 typically can produce up to about 5000 W for example between about 200 W to about 5000 W, or between 1000 W to 3000 W, or about 1500 W and optionally at a tunable frequency in a range from about 50 kHz to about 200 MHz.

The showerhead assembly 130 additionally includes a region transmissive to an optical metrology signal. The optically transmissive region or passage 138 is suitable for allowing the optical monitoring system 140 to view the interior volume 106 and/or the substrate 103 positioned on the substrate support pedestal assembly 148. The passage 138 may be a material, an aperture or plurality of apertures formed or disposed in the showerhead assembly 130 that is substantially transmissive to the wavelengths of energy generated by, and reflected to, the optical monitoring system 140. In one embodiment, the passage 138 includes a window 142 to prevent gas leakage through the passage 138. The window 142 may be a sapphire plate, quartz plate or other suitable material. The window 142 may alternatively be disposed in the chamber lid 104.

The showerhead assembly 130 can be configured with a plurality of zones that allow for separate control of gas flowing into the interior volume 106 of the processing chamber 100. In the example illustrated in FIG. 1, the showerhead assembly 130 as an inner zone 134 and an outer zone 136 that are separately coupled to the gas panel 158 through inlet ports 132′, 132″.

The substrate support pedestal assembly 148 is disposed in the interior volume 106 of the processing chamber 100 below the gas distribution assembly such as showerhead assembly 130. The substrate support pedestal assembly 148 holds the substrate 103 during processing. The substrate support pedestal assembly 148 generally includes a plurality of lift pins (not shown) disposed therethrough that are configured to lift the substrate 103 from the substrate support pedestal assembly 148 and facilitate exchange of the substrate 103 with a robot (not shown) in a conventional manner. An inner liner 118 may closely circumscribe the periphery of the substrate support pedestal assembly 148.

The substrate support pedestal assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among others, to the base 164 and the electrostatic chuck 166. The electrostatic chuck 166 comprises an electrode 180 (e.g., a clamping electrode) for retaining the substrate 103 below showerhead assembly 130. The electrostatic chuck 166 is driven by a chucking power source 182 to develop an electrostatic force that holds the substrate 103 to the chuck surface, as is conventionally known. Alternatively, the substrate 103 may be retained to the substrate support pedestal assembly 148 by clamping, vacuum, or gravity.

A base 164 or electrostatic chuck 166 may include a heater 176, at least one optional embedded isolator 174 and a plurality of conduits 168, 170 to control the lateral temperature profile of the substrate support pedestal assembly 148. The conduits 168, 170 are fluidly coupled to a fluid source 172 that circulates a temperature regulating fluid therethrough. The heater 176 is regulated by a power source 178. The conduits 168, 170 and heater 176 are utilized to control the temperature of the base 164, heating and/or cooling the electrostatic chuck 166 and ultimately, the temperature profile of the substrate 103 disposed thereon. The temperature of the electrostatic chuck 166 and the base 164 may be monitored using a plurality of temperature sensors 190, 192. The electrostatic chuck 166 may further include a plurality of gas passages (not shown), such as grooves, that are formed in a substrate support pedestal supporting surface of the electrostatic chuck 166 and fluidly coupled to a source of a heat transfer (or backside) gas, such as helium (He). In operation, the backside gas is provided at controlled pressure into the gas passages to enhance the heat transfer between the electrostatic chuck 166 and the substrate 103. In embodiments, the temperature of the substrate may be maintained at 20 degrees Celsius to 450 degrees Celsius, such as 100 degrees Celsius to 300 degrees Celsius, or 150 degrees Celsius to 250 degrees Celsius.

The substrate support pedestal assembly 148 can be configured as a cathode assembly and includes an electrode 180 that is coupled to a plurality of RF bias power sources 184, 186. The RF bias power sources 184, 186 are coupled between the electrode 180 disposed in the substrate support pedestal assembly 148 and another electrode, such as the showerhead assembly 130 (or the chamber lid 104) of the chamber body 102. The RF bias power excites and sustains a plasma discharge formed from the gases disposed in the processing region of the chamber body 102.

Still referring to FIG. 1, in some embodiments the dual RF bias power sources 184, 186 are coupled to the electrode 180 disposed in the substrate support pedestal assembly 148 through a matching network 188. The signal generated by the RF bias power sources 184, 186 is delivered through matching network 188 to the substrate support pedestal assembly 148 through a single feed to ionize the gas mixture provided in the plasma processing chamber such as processing chamber 100, thus providing ion energy necessary for performing an etch deposition or other plasma enhanced process. The RF bias power source 184, 186 are generally capable of producing an RF signal having a frequency of from about 50 kHz to about 200 MHz (e.g., about 13.56 MHz+/−5%) and a power between about 0 Watts and about 10,000 Watts (e.g., from about 50 W for low-power operation to about 10,000 W for high-power operation), 1 Watt (W) to about 100 W, or about 1 W to about 30 W. An additional bias power may be coupled to the electrode 180 to control the characteristics of the plasma.

In at least some embodiments, impedances at an Input port and an output port of the matching network 188 and/or the matching network 141 can be measured at all states in a multilevel pulsing. The impedances at the Input port and the output port the matching networks can be used to determine weighted input and output impedances for tuning. For example, apparatus and methods described herein use weighted average tuning in multilevel pulsing. In at least some embodiments, a weighted combination of measured output impedances can be selected for feedforward tuning, and a weighted impedance can be defined from measured input impedances at multilevel pulsing states. Additionally, in at least some embodiments, frequency tuning can used in conjunction with the weighted average tuning for a hybrid tuning. The matching networks described herein can receive a TTL synchronization signal from an RF generator and/or an advanced waveform generator 202 (advanced voltage waveform generator), as described in greater detail below. Alternatively or additionally, the matching networks can receive a TTL synchronization signal that is trigged internally with detected pulse rising or falling edges.

A controller 150 is coupled to the processing chamber 100 to control operation of the processing chamber 100. The controller 150 includes a central processing unit 152, a memory 154, and a support circuit 156 utilized to control the process sequence and regulate the gas flows from the gas panel 158. The central processing unit 152 may be any form of general-purpose computer processor that may be used in an industrial setting. The software routines can be stored in the memory 154, such as random-access memory, read only memory, floppy, or hard disk drive, or other form of digital storage. The support circuit 156 is conventionally coupled to the central processing unit 152 and may include cache, clock circuits, input/output systems, power supplies, and the like. Bi-directional communications between the controller 150 and the various components of the processing chamber 100 are handled through numerous signal cables.

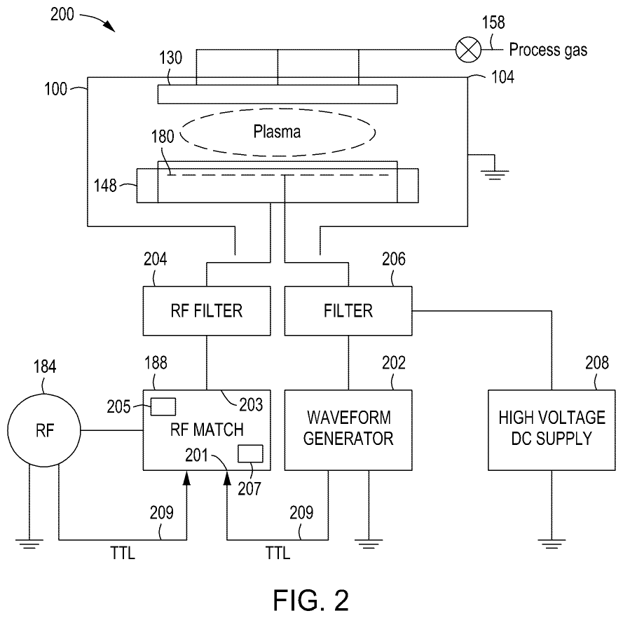

FIG. 2 is a diagram of a system 200, in accordance with at least some embodiments of the present disclosure.

For example, in at least some embodiments, one or more RF power supplies (e.g., the RF bias power source 184 and/or the RF source power 143) can be configured to provide RF power for plasma production to an RF baseplate (e.g., electrostatic chuck 166) of the cathode assembly. In such embodiments, the top electrodes (e.g., the showerhead assembly 130 (or the chamber lid 104)) can be grounded. A frequency of the one or more RF power supplies can be from 13.56 MHz to very high frequency band such as 60 MHz, 120 MHz or 162 MHz. In at least some embodiments, the one or more RF power supplies can also be delivered through the top electrodes. The one or more RF power supplies can be operated in a continuous mode or a pulsed mode. For example, in the pulsed mode, a pulsing frequency can be 100 Hz to about 10 kHz and a duty cycle can be from about 5% to about 95%.

An RF impedance matching network e.g., the matching network 188 and/or the matching network 141)) is connected between the one or more RF power supplies and the processing chamber 100 to optimize power delivery efficiency. The matching network is configured for use with a plasma processing chamber, e.g., a physical vapor deposition chamber, chemical vapor deposition chamber, atomic layer deposition, etch chamber, or other processing chamber that uses a matching network. For illustrative purposes, the matching network (e.g., the matching network 141 and/or the matching network 188) is described herein with respect to an etch chamber, e.g., the processing chamber 100.

The matching network includes an input stage 201 configured to connect to the one or more RF power supplies (e.g., RF bias power sources 184, 186) of a plasma processing chamber and configured to receive one or more radio frequency (RF) signals. The matching network also includes an output stage 203 configured to connect to a substrate support pedestal assembly (e.g., the substrate support pedestal assembly 148) of the processing chamber and configured to deliver the one or more RF signals to a processing chamber.

The matching network includes one or more variable (tunable) capacitors, such as a first variable capacitor 205 (e.g., as series variable capacitor) and a second variable capacitor 207 (e.g., a shunt variable capacitor), which can be connected serially or parallelly to each other. The first variable capacitor 205 and the second variable capacitor 207 have variable capacitances that allow the first variable capacitor 205 and the second variable capacitor 207 to be tuned to one or frequencies. For example, in at least some embodiments, the first variable capacitor 205 and the second variable capacitor 207 can have a capacitance of about 3 pF to about 2500 pF. In at least some embodiments, such as when a processing chamber is operating in a high-power state or low-power state, the first variable capacitor 205 and the second variable capacitor 207 can be tuned to one or more of the above described frequencies, e.g., a target frequency +−10% and a target frequency from 100 kHz to about 250 MHz.

In at least some embodiments, one or more additional capacitors, inductors, transistors, etc. (not shown) can also be provided and connected in parallel and/or series with the first variable capacitor 205 and the second variable capacitor 207.

The first variable capacitor 205 and the second variable capacitor 207 can be the same as each other or different from each other. In at least some embodiments, the first variable capacitor 205 can be coupled to the output stage 203 and the second variable capacitor 207 can be connected to the input stage 201, or vice versa.

In at least some embodiments, one or more RF filters can be connected to the matching network to allow powers in a selected frequency range, and to isolate RF power sources from each other. For example, in at least some embodiments, an RF filter 204 (RF circulator), which is used to regulate and isolate power flow between ports, is connected to the matching network 188 and/or to the substrate support pedestal assembly 148 and/or to the RF bias power source 184 and the matching network 188. In the latter instance, a dummy load 210 can be coupled to the RF filter 204 so that the reflected power can be directed to the dummy load 210.

In at least some embodiments, an advanced waveform generator 202 can used to supply one or more waveforms (e.g., a pulsed voltage waveform and/or a tailored voltage waveform, which can be a sum of harmonic frequencies associated with the tailored voltage waveform). The one or more voltage waveforms can be coupled to a bias electrode (e.g., the electrode 180 of the substrate support pedestal assembly 148) through one or more filter assemblies. For example, in at least some embodiments, an RF filter 206 is connected to the advanced waveform generator 202 and to the electrode 180. The advanced waveform generator 202 can be connected to the matching network 188 and can output a synchronization signal to the matching network 188. For example, in at least some embodiments, the synchronization signal can be a transistor-transistor logic (TTL) 209 signal, as described in greater detail below. Alternatively or additionally, the RF source power can be configured to output a synchronization signal to the matching network 188. Alternatively or additionally, the matching network 188 can be configured to generate an internal synchronization signal, as described in greater detail below.

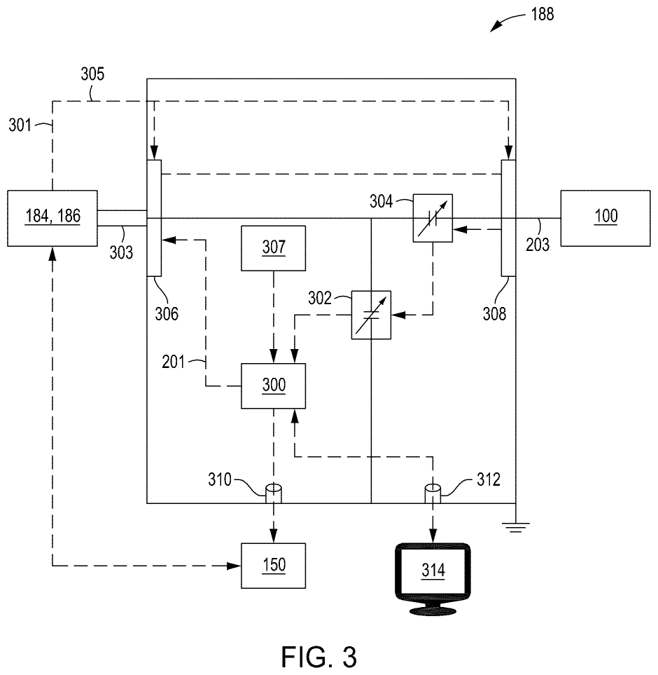

FIG. 3 is a diagram of the matching network 188 configured for use with the processing chamber 100, in accordance with at least some embodiments of the present disclosure. In at least some embodiments, the matching network 188 can be an L type or Pi type matching network.

The matching network 188 comprises a local controller, one or more sensors, and one or more motorized capacitors all of which are connected via EtherCAT (illustrated by the dashed lines 301). EtherCAT is a real time industrial Ethernet protocol, and due to short cycle time and low jitter, EtherCAT provides high speed and accurate synchronization during plasma processing. One or more other interfaces can be used to connect the components of the matching network 188 to each other and/or an RF generator and a plasma processing chamber to the matching network 188. For example, a transmission line 303 (illustrated by the solid lines) can be used to connect an RF generator to the matching network 188 and the matching network 188 to the plasma processing chamber, e.g., in order to supply RF power to the plasma processing chamber.

In at least some embodiments, a local controller 300 functions as a local EtherCAT master, and all matching network components, e.g., sensors, motorized capacitors, are EtherCAT slave devices, which are controlled by the local controller 300. For example, a command sent by the local controller 300 (e.g., EtherCAT master controller) passes to all EtherCAT slave devices. A first motorized capacitor 302 (vacuum capacitor) with EtherCAT interface can be connected to the local controller 300 and to a second motorized capacitor 304 (vacuum capacitor) with EtherCAT interface. The first motorized capacitor 302 can be connected to the second motorized capacitor 304 in a serial or parallel configuration. For example, in the illustrated embodiment, the first motorized capacitor 302 (e.g., a shunt variable capacitor) is connected in parallel with the second motorized capacitor 304 e.g., a series variable capacitor). The first motorized capacitor 302 and the second motorized capacitor 304 are motorized variable capacitors and are configured to be adjusted during operation. For example, the local controller 300 can be configured to adjust the first motorized capacitor 302 and the second motorized capacitor 304 to minimize reflected power during plasma processing.

The local controller 300 can be connected (directly or indirectly) to a first sensor 306 disposed at an input of the matching network 188 and a second sensor 308 (when used) disposed at an output of the matching network 188 for obtaining in-line RF voltage, current, phase, harmonics, and impedance data, respectively. In at least some embodiments, the first sensor 306 and the second sensor 308 can be multi-frequency voltage/current probes. The measured data can be used for automatic impedance tuning, load impedance monitoring, etc.

In at least some embodiments, an interlock circuitry 307 can be connected to the local controller 300 and configured prevent RF generator failure. For example, the interlock circuitry 307 can comprise fault protection circuitries that are configured to shut down RF power output from an RF generator when reflected RF power exceeds a certain percentage of forward power (e.g., >20%), which is RF power sent by an RF generator through the matching network 188 to the load, e.g., plasma in a processing chamber.

As noted above, EtherCAT communication interface connects the local controller 300 to the first motorized capacitor 302, the second motorized capacitor 304, the first sensor 306, and the second sensor 308. The EtherCAT communication interface directly connects an RF generator (e.g., RF bias power sources 184, 186 (and/or RF bias power source 189)) to each of the first sensor 306 and the second sensor 308 for transmitting a TTL signal 305 from the RF generator to each of the first sensor 306 and the second sensor 308, e.g., for fast response and short tune time.

In at least some embodiments, when connected to an RF generator and to a plasma processing chamber, the local controller 300 is configured as an EtherCAT master device, which controls and monitors local EtherCAT slave devices, such as sensors and stepper motors. The local controller 300 is also integrated with an EtherCAT slave controller, so that the local controller 300 can act as an EtherCAT slave device and the controller 150 works as an EtherCAT master device. That is, the local controller 300 is configured to perform a master to slave conversion with the controller 150. The tool controller can be implemented on an industrial computer and embedded with required drivers. In such embodiments, the local controller 300 can receive feedback requests from the controller 150 and provide feedback thereto during plasma processing. For example, the local controller 300 can receive in-line RF voltage, current, phase, harmonics, and impedance data obtained via the first sensor 306 and the second sensor 308. Sensor data and variable capacitor positions can be transmitted to the controller 150, and combined with other system processing data, such as forward and reflected power data from the RF bias power source 184 and the RF bias power source 186, thus creating cooperative intelligent real time control during operation.

The matching network 188 can comprise at least one of a first network port 310, (e.g., a dual RJ45 type port) configured to connect to the controller 150 and a second serial port configured to connect to an external computing device for manual control of the matching network 188 (e.g., laptop or other suitable computing device). For example, in at least some embodiments, the controller 150 can connect to a first network port 310 of the matching network 188 for plasma process control. The local controller 300 can receive in-line RF voltage, current, phase, harmonics, and impedance data obtained via the first sensor 306 and the second sensor 308. Sensor data and variable capacitor positions can be transmitted to the controller 150, and combined with other system processing data, such as forward and reflected power data from the RF bias power source 184 and the RF bias power source 186, thus creating cooperative intelligent real time control during operation. In at least some embodiments, the matching network 188 can include a second serial port 312 that is configured to connect to a computing device 314 for algorithm uploading and for manual control of the matching network, e.g., by using an external software and application programming interface (API). In at least some embodiments, the external software and API can be uploaded and stored the memory 154 and accessed by the controller 150 and/or in a memory (not shown) of the local controller 300. In at least some embodiments, sensor data, which can be obtained from the first sensor 306 and the second sensor 308, can be accessed from the computing device 314. Additionally, when connected to the second serial port 312, the computing device 314 can be configured to control the first motorized capacitor 302 and the second motorized capacitor 304. Providing the first network port 310 and the second serial port 312 provides the matching network 188 with great flexibility when compared to conventional matching networks. For example, advanced process related control algorithms can be deployed in real time and the matching network 188 can operate fully autonomously, cooperatively with the controller 150 and/or manually controlled via the computing device 314. During processing, if needed, the EtherCAT based distributed RF impedance matching networks described herein allows a user using a computing device 314 to fully control the matching network 188 and components associated therewith.

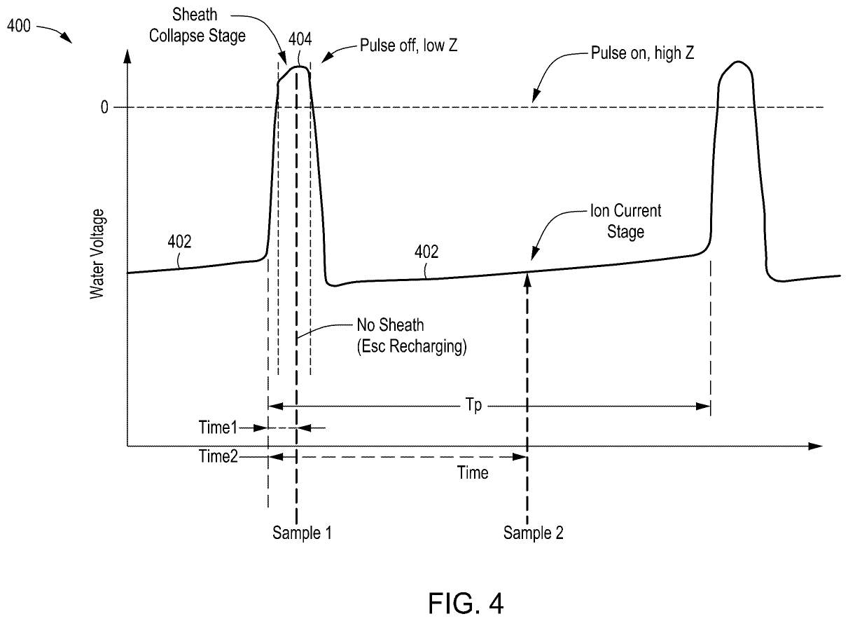

FIG. 4 is a graph 400 of sampling impedances in accordance with at least some embodiments of the present disclosure. For example, in at least some embodiments, voltage waveforms or RF power pulses applied at a substrate (e.g., the substrate 103) within the processing chamber 100 can include two stages. Plasma sheath impedance varies with supplied pulsed voltage waveforms and RF power pulses, and the matching network 188 monitors a TTL synchronization signal from the waveform generator 202 or an RF power supply. For example, in a pulse cycle, two or more pulsed data points can be collected by the matching network 188 to collect impedances at different stages. In at least some embodiments, a first data sample can be collected at a 1st stage for impedance Z₁ (e.g., at 404, which can correspond to a sheath collapse stage) and a second data sample can be collected at a 2 nd stage for impedance Z₂ (e.g., at 402, which can correspond to ion current stage). The collected data samples can be used to obtain weighted impedance values. In at least some embodiments, data samples need to be collected after a time delay, which is defined based on, for example, a pulsing frequency, a duty cycle, and/or a rising edge of the TTL synchronization signal.

In at least some embodiments, a high voltage DC supply 208 can be used to supply power to the electrode 180 to chuck the substrate (e.g., a wafer) during processing for thermal control. In at least some embodiments, a third electrode (not shown) can be provided at an edge of the cathode assembly for edge uniformity control. In such embodiments, a third low frequency RF power supply in the frequency range of 50 kHz to 2 MHz can be delivered to the edge electrode and run at a continuous mode.

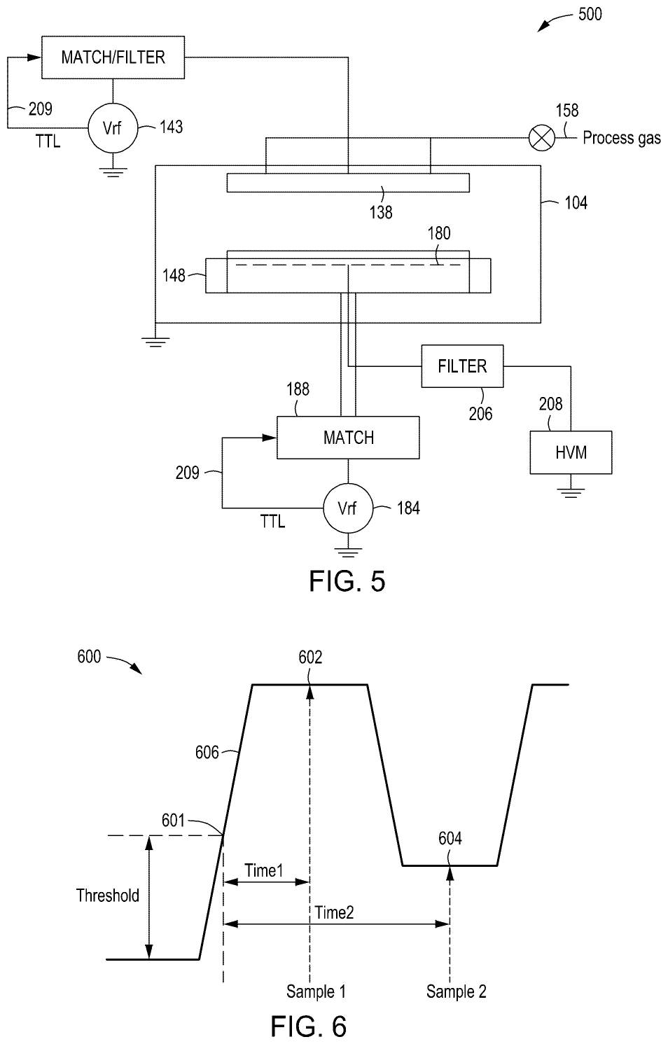

FIG. 5 is a diagram of a system 500 in accordance with at least some embodiments of the present disclosure. The system 500 is substantially identical to the system 200. Accordingly, only those features that are unique to the system 500 are described herein.

For example, one or more RF power supplies (e.g., the RF source power 143) is connected to a top electrode for plasma production. The frequency of the one or more RF power supplies can operate in a frequency from about 13.56 MHz to about 200 MHz, such as 60 MHz, 120 MHz or 162 MHz as needed. The one or more RF power supplies can be operated in a continuous or a pulsed mode. The pulsing frequency can be from 100 Hz to 10 kHz and the duty cycles can be from about 5% to about 95%. An RF bias power (e.g., the RF bias power source 184) is connected to the bottom electrode with a frequency range from about 100 kHz to about 15 MHz. The RF bias power can be operated in either a continuous or a pulsed mode. The pulsing frequency can be from 100 Hz to 10 kHz and the duty cycles can be from about 5% to about 95%. One or both of the RF source power 143 and the RF bias power can be configured to send a synchronization TTL signal to the matching network 141 and the matching network 188, respectively. As noted above, a third electrode can be used at an edge of the cathode assembly for edge uniformity control. In such embodiments, a third low frequency RF power supply in the frequency range of 50 kHz to 2 MHz can be delivered to the edge electrode and run at a continuous mode. Similar to the system 200, RF filters can be connected to the matching network 188 (not shown), connected to the matching network 141 and the high voltage DC supply 208. In at least some embodiments, an RF filter can be connected to the matching network 188.

FIG. 6 is a diagram 600 of internal synchronization for dual level pulsing, in accordance with at least some embodiments of the present disclosure. For example, as described above, to obtain impedance values for determining a weighted average, a trigger signal can be generated externally (e.g., via the one or more RF power supplies or an advanced waveform generator) or internally (e.g., via the matching networks). In the latter embodiment, voltage and current sensors (e.g., a first sensor 306 and a second sensor 308) of the matching network are configured to detect a start of pulse signal internally. The voltage and current sensors can sense multiple impedance samples during a pulse cycle. For example, at a first sample time and at a second sample time that are defined relative to a start of the trigger signal, typically the rising edge of the pulse. Multiple impedances can be measured in the same pulse level or different levels and can be used in a weighted average tuning algorithm. Accordingly, the matching networks use a weighted impedance from all measured samples in the same pulse level or different levels.

The collected data samples can be measured in a pulse or averaged from multiple pules, e.g., a threshold value 601 can be defined for pulse detection. The threshold value 601 can be set between two pulse state levels. A start of pulses is detected when voltages measured by sensor (not shown) go above the threshold value 601. In at least some embodiments, a sample 1 and a sample 2 can be taken from different pulses. In at least some embodiments, a sample 1 and a sample 2 can be an average of many pulsed data points collected from multiple pulses. For example, in at least some embodiments to calculate averaged values, pulse high states can be measures ten times in ten pulses to get an averaged sample 1, and pulse low states can be measured ten times in the same or different ten pulses to get an averaged sample 2. Data point measurements are triggered after a delay of a first sample time and a second sample time relative to the start of the pulse. The first sample time and the second sample time determine when measurements are taken in the pulse.

For example, a first data sample 602 and a second data sample 604 can be collected at a high state and a low state, respectively, by defining the first pulse time and the second pulse time with respect to a trigger signal, for example, a rising edge 606 of the pulse.

The inventors have found that plasma load impedance can vary with multilevel pulse states due to different power levels or mixes of RF power supplies (e.g., the RF bias power source 184 and the RF source power 143). Additionally, vacuum capacitor motors, which are, typically, used in conventional matching networks, cannot respond quickly enough (e.g., move) in a pulse cycle, conventional matching networks are not capable of tuning to both impedances at the same time.

Thus, the inventors have provided a weighted combination of impedances (e.g., various impedance samples obtained either via external or internal triggers) for single or multi-level pulsing. For example, in a dual level pulsing, using one or both of the external or internal triggers, a first impedance Z₁ can be measured at a first sample time at a first pulse level, and a second impedance Z₂ can be measured at a second sample time at a second pulse level. A weighted target impedance can then be calculated using the Equation (1):

Z_{w}=*w+Z₂*(1−w), w from 0 to 1, (1)

where w is a weight value between 0 and 1. In at least some embodiments, a multistate weighting algorithm can also be used, where more weight values may be needed. For example, w1 and w2 can be weight values in a triple level pulsing situation. In operation, the weighted target impedance of the matching networks described herein change with weight values during dual impedance states. For example, when w is equal to zero, the matching networks tune to an impedance equal to a second level in the pulse, whereas the matching networks tune to an impedance equal to a first level when w is equal to one.

In at least some embodiments, an optimized w value can be determined based on minimum total reflected power for both states. For example, using reflected power changes with a weight value in a dual level pulsing. For example, a first level can have a minimum reflected power at w=1, and a second level can have minimum one at w=0. For example, when w=0.8, total reflected power for both states is at the minimum. Other criteria can also be used for selecting an appropriate weight value.

Similarly, the matching networks provide measured and weighted output impedances in a dual level (or multilevel) pulsing. For example, a plasma load impedance can vary with pulsing power levels, bias power on and off, or pulsed voltage waveforms. Accordingly, Z₁ and Z₂ can be measured impedances at an output of the matching networks, again with either external or internal synchronization. As noted above, since motors in conventional matching networks are not capable of follow the fast-changing impedance states, a weighted output impedance can be calculated and used as a target plasma load impedance. For example, in at least some embodiments, a weighted impedance at the output of the matching network can be used in a feedforward tuning algorithm as a tuning goal.

In at least some embodiments, the weighted input impedance and weighted output impedance can be stored in a look-up table (e.g., in the memory 154) or a circuit model can be used to move variable capacitors inside the RF match directly to target positions. In some embodiments, learning based tuning algorithm can be adopted to find a proper weighted target impedance at the RF match input and/or output.

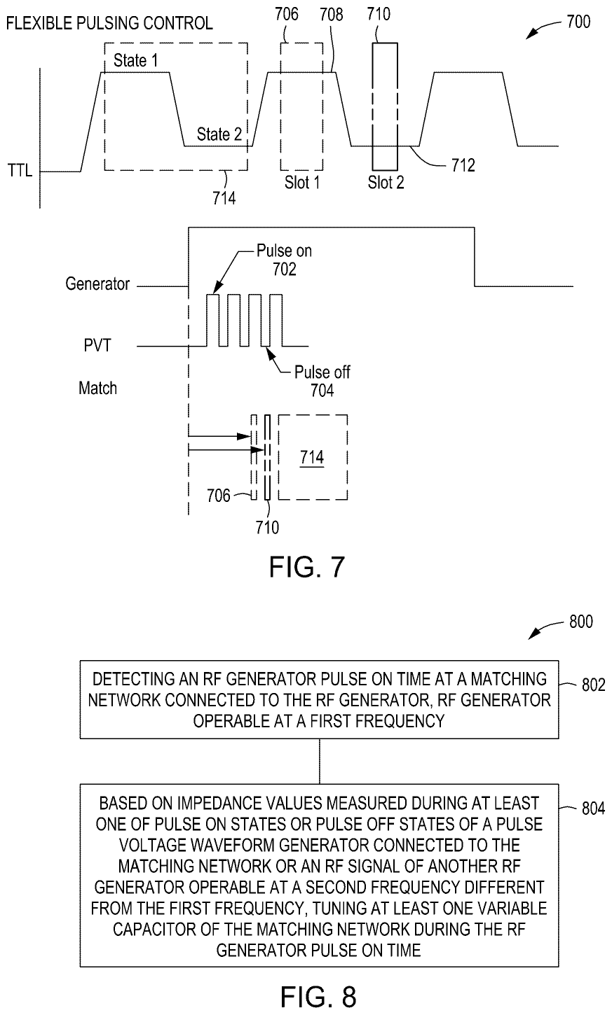

FIG. 7 is a diagram 700 of internal synchronization for flexible pulsing control, in accordance with at least some embodiments of the present disclosure. For example, the inventors have found that during operation a matching network (e.g., the matching network 188) can be configured to take impedance measurements (e.g., impedance lock tuning) during pulse on times and/or pulse off times of the advanced waveform generator 202. For example, the matching network 188 can take impedance measurements at one or more time slots (e.g., a data window) that correspond to the pulse on time and/or pulse off time of the advanced waveform generator 202. The one or more slots are flexible and can have a varying width and accumulation for multilevel pulsing. In at least some embodiments, the one or more slots can have a slot time of about 10 ns to about 100 μs and a slot width of about 0.1 μs to about 50 μs. In at least some embodiments, the matching network 188 can be configured to take impedance measurements during only pulse on times 702 of the advanced waveform generator 202. For example, the matching network 188 can use a slot 706 corresponding to only pulse on times 702 (Z₁) of the advanced waveform generator 202. The slot 706 time and slot 706 width fits within the on state 708 of a TTL logic signal received from the RF bias power sources 184, 186. The on state of the TTL logic signal corresponds to no sheath at 402 (measurements taken at relatively high impedance). Additionally or alternatively, in at least some embodiments, the matching network 188 can use a slot 710 (which can be different from or the same as the slot 706) corresponding to only pulse off times 704 (Z₂) of the advanced waveform generator 202. The slot 710 time and slot 710 width fits within the off state 712 of a TTL logic signal received from the RF bias power sources 184, 186. The off state 712 of the TTL logic signal corresponds to the sheath collapse state at 404 (relatively low impedance). When taking the impedance measurements during only the pulse on times 702 (or the pulse off times 704), the matching network 188 tunes and locks to the pulse on times 702 and/or pulse off times 704 of the advanced waveform generator 202, higher etch rates can be obtained when compared to tune time averaging impedance measurements. The slot 706 and the slot 710 can be changed based on at least one of the advanced waveform generator 202 pulse on states and the pulse off states (e.g., 5% to about 95% of the pulse on states and the pulse off states), the advanced waveform generator 202 pulsing frequency (e.g., 10 kHz to about 500 kHz), the RF bias power sources duty cycle (e.g., RF generator duty cycle of about 1% to about 99%), or the RF bias power sources pulsing frequency (1 Hz to about 500 kHz). Additionally, during tuning, the matching network 188 can repeat the impedance measurements for averaging the impedance values.

Additionally or alternatively, in at least some embodiments, matching network 188 can use a slot 714 corresponding to pulse on times 702 and pulse off times 704 of the advanced waveform generator 202. The slot 714 time and slot 714 width fits across one or more of the on state 708 and the off state 712 of a TTL logic signal received from the RF bias power sources 184, 186. In such embodiments, the matching network can use the weighted average calculations as described above (Z₁ and Z₂).

In at least some embodiments, such as when multilevel pulsing is used by the RF bias power sources, the matching network 188 can tune to the rising edge or falling edge of the multilevel pulsing signal. For example, the matching network can use the slot 706 for tuning to a first level of the multilevel pulsing signal and can use the slot 710 (which can be different from or the same as the slot 706) for tuning a second level of the multilevel pulsing signal.

In at least some embodiments, such as when the advanced waveform generator 202 is not used and a second RF bias power source (e.g., the RF bias power source 186) is used in conjunction with the RF bias power source 184, two matching networks 188 (e.g., two independent matching networks) can be configured to perform impedance matching as described above. For example, the RF bias power source 186, which can operate at a frequency of about 100 kHz to about 20 MHz, can be connected to a first matching network and the RF bias power source 184, which can operate at a frequency of about 10 MHz 180 MHz, can be connected to a second matching network. Each of the first matching network and the second matching network can operate as described above with respect to the matching network 188. Additionally, in embodiments, when two RF bias sources are used, the advanced waveform generator 202 can be used as described above with one or both of the RF bias sources.

FIG. 8 is a flowchart of a method 800 of processing a substrate in accordance with at least some embodiments of the present disclosure. For illustrative purposes, the method 800 is described herein using the processing chamber 100 for etching the substrate 103.

At 802, the method 800 comprises detecting an RF generator, which is operable at a first frequency, pulse on time at a matching network connected to the RF generator. For example, the matching network 188 can receive a TTL synchronization signal from the RF bias power source 184 (which can operate at a pulsing frequency of about 1 Hz to about 500 kHz), the advanced waveform generator 202, and/or receive a TTL synchronization signal that is trigged internally with detected pulse rising or falling edges.

Next, at 804, the method 800 comprises, based on impedance values measured during at least one of pulse on states or pulse off states of a pulse voltage waveform generator (e.g., the pulse voltage waveform generator pulse on state and/or the pulse voltage waveform generator pulse off state) connected to the matching network (e.g., the matching network 188) or an RF signal of another RF generator operable at a second frequency different from the first frequency (e.g., the RF bias power source 186 operates at a frequency of about 100 kHz to about 20 MHz), tuning at least one variable capacitor of the matching network during the RF generator pulse on time. For example, in at least some embodiments, the matching network 188 can measure impedance values during a slot for taking impedance measurements that correspond to a pulse on time (e.g., measured during pulse on time of the advanced waveform generator 202) and/or to a pulse off time (e.g., measured during pulse off time of the advanced waveform generator 202). The variable capacitor (e.g., the second motorized capacitor 304) can be lock tuned based on output impedance values and input impedance values measured only at the pulse on states of the advanced waveform generator 202. Similarly, the variable capacitor (e.g., the second motorized capacitor 304) can be tuned based on output impedance values and input impedance values measured only at the pulse off states of the advanced waveform generator 202. In at least some embodiments, the variable capacitor (e.g., the second motorized capacitor 304) can be lock tuned to pulsed voltage waveform combined states when more RF power is applied, e.g., using customized sensor data collection window, the matching network 188 can lock tune to specific impedances at different power combination conditions.

Similarly, when two RF bias power sources are used in conjunction with each other (e.g., with or without the waveform generator 202), each matching network connected to a respective RF bias power source can be configured to measure impedance using the methods described above. In at least some embodiments, the respective matching networks can communicate measured impedances to each other when tuning the variable capacitor. In at least some embodiments, as an RF bias power source 186 signal is effectively an infinite sine wave, a measuring slot time (window) of the RF bias power source 186 can measure impedance Z using a relatively small measurement slot times at selected ranges (e.g., the measuring slot time can correspond to the peaks (and/or troughs) of the RF bias power source 186 signal). Alternatively or additionally, as the RF bias power pulse on time is, typically, longer than the measuring measurement slot times, in at least some embodiments, the matching network can tune lock using a time averaged impedance Z, see Equation 1 as described above.

In at least some embodiments, the at least one capacitor can comprise two variable capacitors (e.g., first motorized capacitor 302 and the second motorized capacitor 304. In such embodiments, the at least two variable capacitors can be tuned at the same time or at different times.

In at least some embodiments, such as when the second sensor 308 is not used, the variable capacitor can be tuned based on output impedances that are stored in a look-up table (e.g., in the memory 154) or a circuit model.

In at least some embodiments (e.g., in a single level pulse signal configuration, which comprises RF signals provided by an RF bias power source, RF signals provided by an RF source power, and/or pulsed voltage waveforms) the impedance values can be obtained from only the pulse on states or the pulse off states of the advanced waveform generator 202. Additionally, the first sample time and the second sample time can be the same or different and are based on at least one of a pulse frequency, duty cycle, or a rising edge of a Transistor-Transistor Logic (TTL) synchronization signal.

Similarly, in at least some embodiments (e.g., in a multi-level pulse signal configuration, which comprises at least one of RF signals provided by an RF power source, and/or pulsed voltage waveforms) the impedance values can be obtained at a high level pulse stage and a low level pulse stage. In such embodiments, the high level pulse stage is taken at a first sample time and the low level pulse stage is taken at a second sample time that is different from the first sample time. Additionally, the first sample time and the second sample time are triggered after a delay from a start of a pulse detected when measured voltage of a pulse is equal to or greater than a threshold.

In at least some embodiments, such as when a pulse voltage waveform generator is used, the matching network 188 can be configured to tune the at least one variable capacitor based on sideband data of the pulse on states of the pulse voltage waveform generator that is reflected back to the RF bias power source 184. Alternatively or additionally, in at least some embodiments, such as when impedance matching is performed during pulse off states of the pulse voltage waveform generator, the matching network 188 is configured to tune the at least one variable capacitor based on the nominal sideband data that is reflected back to the RF bias power source 184.

The calculated impedance values are stored in the memory 154 and automatically accessed by the controller 150 during operation at 804 to tune the first variable capacitor and/or the second variable capacitor to the weighted target impedance values.

While the foregoing is directed to embodiments of the present disclosure, other and further embodiments of the disclosure may be devised without departing from the basic scope thereof.

1. A matching network configured for use with a plasma processing chamber, comprising:
a first sensor operably connected to an input of the matching network and an RF generator operable at a first frequency and a second sensor operably connected to an output of the matching network and the plasma processing chamber, the first sensor and the second sensor configured to measure impedance during an RF generator pulse on time;
at least one variable capacitor connected to the first sensor and the second sensor; and
a controller configured to tune the at least one variable capacitor of the matching network during the RF generator pulse on time based on impedance values measured during at least one of pulse on states or pulse off states of a pulse voltage waveform generator connected to the matching network or an RF signal of another RF generator operable at a second frequency different from the first frequency.

2. The matching network of claim 1, wherein when the controller is configured to tune the at least one variable capacitor of the matching network during pulse on states or pulse off states of the pulse voltage waveform generator, a time slot for taking impedance measurements during the pulse on states and the pulse off states are based on at least one of a pulse voltage waveform generator pulse on time, a pulse voltage waveform generator pulse off time, a pulse voltage waveform generator pulsing frequency, an RF generator duty cycle, or an RF generator pulsing frequency.

3. The matching network of claim 2, wherein the time slot of the pulse on states and the pulse off states are based on a percentage of the pulse voltage waveform generator pulse on time and/or the pulse off time and the percentage is about 5% to about 95%.

4. The matching network of claim 2, wherein the time slot of the pulse on states and the pulse off states are based on the pulse voltage waveform generator pulsing frequency and the pulse voltage waveform generator pulsing frequency is about 10 kHz to about 500 kHz.

5. The matching network of claim 2, wherein the time slot of the pulse on states and the pulse off states are based on the RF generator duty cycle and the RF generator duty cycle is about 1% to about 99%.

6. The matching network of claim 2, wherein the time slot of the pulse on states and the pulse off states are based on the RF generator pulsing frequency and the RF generator pulsing frequency is about 1 Hz to about 500 kHz.

7. The matching network of claim 2, wherein the time slot of the pulse on states and the pulse off states has a resolution of about 10 ns to about 100 μs.

8. The matching network of claim 2, wherein the time slot of the pulse on states and the pulse off states has a width of about 0.1 μs to about 50 μs.

9. The matching network of claim 1, wherein the controller is further configured to tune the at least one variable capacitor based on sideband data of the pulse on states.

10. The matching network of claim 1, wherein the controller is further configured to tune the at least one variable capacitor of the matching network during operation based on impedance values measured during pulse on states.

11. The matching network of claim 1, wherein the controller is further configured to tune the at least one variable capacitor of the matching network during operation based on impedance values measured during pulse off states.

12. The matching network of claim 1, wherein when the controller is configured to tune the at least one variable capacitor of the matching network during the RF signal of another RF generator, a time slot for taking impedance measurements is based on a selected range corresponding to at least one of a peak or a trough of the RF signal.

13. The matching network of claim 12, wherein RF generator operates at a frequency of about 10 MHz to about 180 MHz and another RF generator operates at frequency of about a 100 kHz to about 20 MHz.

14. A plasma processing chamber, comprising:
a chamber body and a chamber lid;
a RF generator operable at a first frequency connected to the chamber lid and configured to create a plasma from gases disposed in a processing region of the chamber body; and
a matching network comprising:
a first sensor operably connected to an input of the matching network and the RF generator and a second sensor operably connected to an output of the matching network and the plasma processing chamber, the first sensor and the second sensor configured to measure impedance during an RF generator pulse on time;
at least one variable capacitor connected to the first sensor and the second sensor; and
a controller configured to tune the at least one variable capacitor of the matching network during the RF generator pulse on time based on impedance values measured during at least one of pulse on states or pulse off states of a pulse voltage waveform generator connected to the matching network or an RF signal of another RF generator operable at a second frequency different from the first frequency.

15. The plasma processing chamber of claim 14, wherein when the controller is configured to tune the at least one variable capacitor of the matching network during pulse on states or pulse off states of the pulse voltage waveform generator, a time slot for taking impedance measurements during the pulse on states and the pulse off states are based on at least one of a pulse voltage waveform generator pulse on time, a pulse voltage waveform generator pulse off time, a pulse voltage waveform generator pulsing frequency, an RF generator duty cycle, or an RF generator pulsing frequency.

16. The plasma processing chamber of claim 15, wherein the time slot of the pulse on states and the pulse off states are based on a percentage of the pulse voltage waveform generator pulse on time and/or the pulse off time and the percentage is about 5% to about 95%.

17. The plasma processing chamber of claim 15, wherein the time slot of the pulse on states and the pulse off states are based on the pulse voltage waveform generator pulsing frequency and the pulse voltage waveform generator pulsing frequency is about 10 kHz to about 500 kHz.

18. The plasma processing chamber of claim 15, wherein the time slot of the pulse on states and the pulse off states are based on the RF generator duty cycle and the RF generator duty cycle is about 1% to about 99%.

19. The plasma processing chamber of claim 15, wherein the time slot of the pulse on states and the pulse off states are based on the RF generator pulsing frequency and the RF generator pulsing frequency is about 1 Hz to about 500 kHz.

20. A method for processing a substrate, comprising:
detecting an RF generator pulse on time at a matching network connected to the RF generator, RF generator operable at a first frequency; and
based on impedance values measured during at least one of pulse on states or pulse off states of a pulse voltage waveform generator connected to the matching network or an RF signal of another RF generator operable at a second frequency different from the first frequency, tuning at least one variable capacitor of the matching network during the RF generator pulse on time.
